(19) United States
(12) Patent Application Publication
(10) Pub. No.: US 2015/0179857 A1
(43) Pub. Date: Jun. 25, 2015

(54) SEMICONDUCTOR EPITAXIAL STRUCTURES AND SEMICONDUCTOR OPTOELECTRONIC DEVICES COMPRISING THE SAME

(71) Applicant: EPISTAR CORPORATION, Hsinchu (TW)

(72) Inventor: Shiuan-Leh LIN, Hsinchu (TW)

(21) Appl. No.: 14/632,167

(22) Filed: Feb. 26, 2015

Related U.S. Application Data
(63) Continuation-in-part of application No. 13/103,412, filed on May 9, 2011, now abandoned.

(30) Foreign Application Priority Data
May 12, 2010 (TW) 099115262

(51) Int. Cl. H01L 31/0687; H01L 31/0725; H01L 33/30; H01L 31/0236; H01L 31/0304; H01L 31/0693; H01L 31/0735

(52) U.S. Cl. CPC H01L 31/0687; H01L 31/0693; H01L 31/0725; H01L 31/0735; H01L 31/02363; H01L 31/0304; H01L 31/03046; H01L 33/30

(57) ABSTRACT

An optoelectronic device comprises a substrate; a converting structure for converting energy between light and electric current over the substrate; and a semiconductor buffer layer combination between the substrate and the converting structure, the semiconductor buffer layer combination comprising multiple first semiconductor layers and multiple second semiconductor layers alternately stacked, wherein each of the multiple first semiconductor layers comprises a first element, each of the multiple second semiconductor layers comprises a second element different from the first element, and the composition ratio of the first element gradually increases or decreases with an increase of the distance between the first semiconductor layers and the substrate.

### REFERENCE TO RELATED APPLICATION

This application is a continuation-in-part of U.S. patent application Ser. No. 13/103,412, entitled “Semiconductor Epitaxial Structures And Semiconductor Optoelectronic Devices Comprising The Same”, filed on May 9, 2011, which claims the right of priority based on Taiwan application Serial No. 099115262, filed on May 12, 2010, which disclosures are hereby incorporated by reference in their entireties.

### TECHNICAL FIELD

The disclosure relates to a semiconductor epitaxial structure, and a semiconductor optoelectronic device which comprises the semiconductor epitaxial structure. More particularly, to a semiconductor epitaxial structure with stress balance and an optoelectronic device which comprises the semiconductor epitaxial structure.

### DESCRIPTION OF BACKGROUND ART

Along with the development of the economy, in order to raise the output of the products and to gain more profit, the labor work has been done by machine gradually. After the industrial revolution, the electricity becomes the main power source, and the way to source of electricity also becomes an international issue. Comparing with the contaminating energy such as the petroleum, the coal, and the nuclear energy, the solar energy makes no pollution and provides energy of 180 watts per meter square to the surface of the earth without being monopolized. Therefore, the solar energy has become one of the most potential energy in the future.

Since the first solar cell produced in Bell's laboratory in the United States in 1954, various kinds of solar cells with different structures were disclosed consecutively. The solar cells could be classified into the silicon-based solar cell, the multi junction semiconductor solar cell, the dye sensitized solar cell, and the organic conductive polymer solar cell and so on in accordance with the difference of the materials. In accordance with FIG. 1, take the conventional silicon-based solar cell device 1 for example, the structure comprises a first electrode 12, a silicon substrate 17, a p-type silicon semiconductor layer 14, an n-type silicon semiconductor layer 15, and a second electrode 16. The sun light 10 illuminates the solar cell device 1 and provides the p-type silicon semiconductor layer 14 and the n-type silicon semiconductor layer 15 the energy which is larger than the band gap of the silicon semiconductor layer. After the atoms in the silicon semiconductor layer absorbing the energy, the free carriers (electrons/holes) are generated. The electrons move toward the n-type silicon semiconductor layer 15, the holes move toward the p-type silicon semiconductor layer 14, and the electric potential difference is produced because the positive and the negative charges accumulate near the p-n junction between the p-type silicon semiconductor layer 14 and the n-type silicon semiconductor layer 15. Due to the electric potential difference, the accumulated electrons flow to the external circuit (not shown in the FIGS.) from the first electrode 12 to the second electrode 16, and the current is produced in the external circuit. Meanwhile, if a load (not shown in the FIGS.) is added in the external circuit, the produced electric energy could be collected and stored. Herein, the combination of the p-type silicon semiconductor layer 14 and the n-type silicon semiconductor layer 15 which could absorb light with a specific wavelength range and produce a current in the external circuit is called a subcell 11.

FIG. 2 shows the spectrum of the solar energy radiation on the surface of the earth. In accordance with the spectrum, besides the visible light, the distribution of the solar energy on the surface of the earth also covers the IR and the ultraviolet light. However, in accordance with the aforementioned operation principle of the solar cell, in the traditional semiconductor solar cell structure, only the solar energy equal to or larger than the band gap of the semiconductor layer could be absorbed. Take the silicon for example, the band gap of the silicon is about 1.12 eV, it can only absorb part of the energy with the wavelength in the IR range in the spectrum. Besides, take the internal loss of the solar cell into consideration, the conversion efficiency of the solar cell is low.

In order to improve the aforementioned problem, a multi junction solar cell is developed and has become one with the highest conversion efficiency.

Refer to FIG. 3, a multi junction tandem solar cell device 3 comprises three subcells (p-n junctions) of Ge/Ga_{0.83}In_{0.17}As/Ga_{0.35}In_{0.65}P in the device. The multi junction tandem solar cell device 3 is stacked by a first electrode 32, a Ge substrate 35, a first subcell 31 with a composition of Ge, a second subcell 33 with a composition of Ga_{0.83}In_{0.17}As, a third subcell 34 with a composition of Ga_{0.35}In_{0.65}P, and a second electrode 36. Wherein, each subcell comprises one p-n junction formed by the combination of one p-type semiconductor layer and one n-type semiconductor layer. Accordingly, the Ge first subcell 31 comprises one p-n junction formed by the combination of one p-type Ge semiconductor material layer 311 (p-Ge) and one n-type Ge semiconductor material layer 312 (n-Ge); the GaInAs second subcell 33 comprises one p-n junction formed by the combination of one p-type Ga_{0.83}In_{0.17}As semiconductor material layer 331 (p-Ga_{0.83}In_{0.17}As) and one n-type Ga_{0.83}In_{0.17}As semiconductor material layer 332 (n-Ga_{0.83}In_{0.17}As); the Ga_{0.35}In_{0.65}P third subcell 34 comprises one p-n junction formed by the combination of one p-type Ga_{0.35}In_{0.65}P semiconductor material layer 341 (p-Ga_{0.35}In_{0.65}P) and one n-type Ga_{0.35}In_{0.05}P semiconductor material layer 342 (n-Ga_{0.35}In_{0.65}P). When the sun light 30 illuminates, in order to let the solar energy absorbed by the aforementioned multi subcells efficiently, the subcell nearest the sun is preferred a subcell with the largest semiconductor band gap, and the band gaps decrease as the distance of each subcell related to the sun increases. Accordingly, the band gap of the Ga₀₃₅In_{0.65}P third subcell 34 is larger than the band gap of the Ga_{0.83}In_{0.17}As second subcell 33, and the band gap of the Ga_{0.83}In_{0.17}As second subcell 33 is larger than the band gap of the Ge first subcell 31.

Besides, there is a first tunnel junction 38 between the first subcell 31 and the second subcell 33 and a second tunnel junction 39 between the second subcell 33 and the third subcell 34. The tunnel junctions are located between the subcells to adjust the resistance between two adjacent subcells, to reduce the charges accumulated near any sides of the two adjacent subcells, and to match the currents of the subcells. Further, to achieve a higher optoelectronic converting efficiency, an anti-reflective layer 37 could be optionally formed between the first electrode 32 and the third subcell 34 to reduce the reflection from the structure surface.

When the sun light 30 passes through the upper Ga_{0.35}In_{0.65}P third subcell 34 with high band gap (˜1.66 eV), the photon with higher energy is absorbed (the range is about from the ultraviolet to the visible light). The central Ga_{0.83}In_{0.17}As second subcell 33 absorbs the photon with the energy from the visible light to the IR region because its band gap is smaller than that of the Ga_{0.35}In_{0.65}P third subcell 34. The central Ga_{0.83}In_{0.17}As second subcell 33 also re-absorbs light with high energy which is not absorbed by the upper Ga_{0.35}In_{0.65}P third subcell 34 and is transmitted from the upper subcell to the central subcell so the solar energy is used more efficiently. Finally, because the Ge first subcell 31 comprises the lower band gap, it could absorb the light with the energy larger than the IR light passing through the upper two subcells again. Referring to FIG. 4, FIG. 4 shows the spectrum response diagram of the multi junction tandem solar cell device 3. One coordinate axis shows the absorbed wavelength and the other coordinate axis shows the percent of the quantum efficiency. The higher the quantum efficiency is, the more efficiently the selected material absorbs the light with the corresponding wavelength and converts it into the electron-hole pairs in the solar cell. As shown in FIG. 4, because the band gaps of the multi junction solar cell with a composition of Ge/Ga_{0.83}In_{0.17}As/Ga_{0.35}In_{0.65}P increase gradually from the substrate and the range of the absorbed wavelength is broader and overlapped alternatively, the solar energy could be used repeatedly and the solar cell could achieve a very high quantum efficiency in various wavelength range. Therefore, by taking advantage of this kind of stacked multi junction solar cell, the higher conversion efficiency could be achieved.

Nevertheless, when choosing the material of each subcell in one multi junction tandem solar cell, it should consider if the band gaps between the different subcells match as well as the lattice constants of the materials in each subcell to reduce the defects during the manufacturing process and to achieve the higher converting efficiency. Generally, it is considered mismatched when the difference of the lattice constants between the subcell is over 0.05% .

In detail, referring to FIG. 3, the structure of the multi junction tandem solar cell device 3 from bottom to top is the Ge substrate 35, the Ge first subcell 31, the Ga_{0.83}In_{0.17}As second subcell 33, and the Ga_{0.35}In_{0.65}P third subcell 34. The lattice constant of the Ge substrate 35 and the Ge first subcell 31 is 5.658 A so the lattices are matched. However, the lattice constant of the Ga_{0.83}In_{0.17}As second subcell 33 is about 5.722 A, compared with the Ge first subcell 31, the difference of the lattice constant between the adjacent Ga_{0.83}In_{0.17}As second subcell 33 is [(5.722−5.6580)/5.658]×100%≈1.13%, which is lattice mismatched. Accordingly, when epitaxially growing the Ge first subcell 31 and the Ga_{0.83}In_{0.17}As second subcell 33, the growth stress could produce in the device and lead to the lattice defect. Besides, the stress could cause bending or cracking that influences the quality and the yield of the devices. Except for the multi junction tandem solar cell mentioned above, the epitaxially formed semiconductor optoelectronic device such as the light-emitting diode and so on may also have the similar situation. That is, the inner stress may arise because of the difference of the lattice constant between adjacent epitaxially structures and lead to the lattice defect. Besides, the stress could cause bending or cracking that influences the quality and the yield of the devices.

### SUMMARY OF THE DISCLOSURE

The present disclosure provides an optoelectronic device comprising a substrate; a converting structure for converting energy between light and electric current over the substrate; and a semiconductor buffer layer combination between the substrate and the converting structure, the semiconductor buffer layer combination comprising multiple first semiconductor layers and multiple second semiconductor layers alternately stacked, wherein each of the multiple first semiconductor layers comprises a first element, each of the multiple second semiconductor layers comprises a second element different from the first element, and the composition ratio of the first element gradually increases or decreases with an increase of the distance between the first semiconductor layers and the substrate.

### BRIEF DESCRIPTION OF THE DRAWINGS

FIG. 1 illustrates a conventional silicon based solar cell device;

FIG. 2 illustrates a spectrum of the radiation of the solar energy on the surface of earth;

FIG. 3 illustrates a conventional multi junction tandem solar cell device;

FIG. 4 illustrates a spectrum response diagram of the multi junction tandem solar cell device shown in FIG. 2;

FIG. 5 illustrates a multi junction tandem solar cell device in accordance with one embodiment of the present application;

FIG. 6 illustrates an enlarged sketch of the semiconductor buffer layer combination part of the multi junction tandem solar cell device in accordance with one embodiment of the present application;

FIG. 7 illustrates a light emitting diode device in accordance with one embodiment of the present application;

FIG. 8 illustrates an enlarged sketch of the semiconductor buffer layer combination part of the light emitting diode device in accordance with one embodiment of the present application.

FIG. 9 shows an optoelectronic device in accordance with another embodiment of the present application.

FIGS. 10A and 10B show respectively the measurement results of reflectivity for the DBR structures for reflecting light having a maximum reflectivity at a light wavelength of about 807 nm and about 670 nm which are formed in accordance with the embodiment of the present application shown in FIG. 9.

FIG. 11A shows an optoelectronic device in accordance with another embodiment of the present application.

FIGS. 11B to 11C show the process to form the optoelectronic device in FIG. 11A.

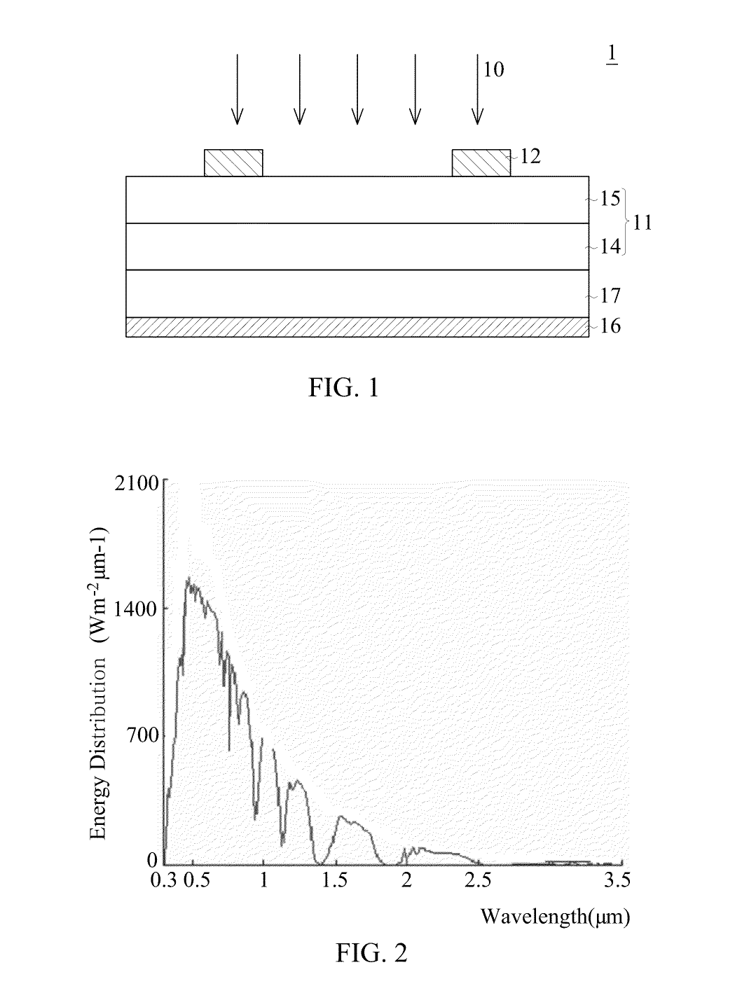

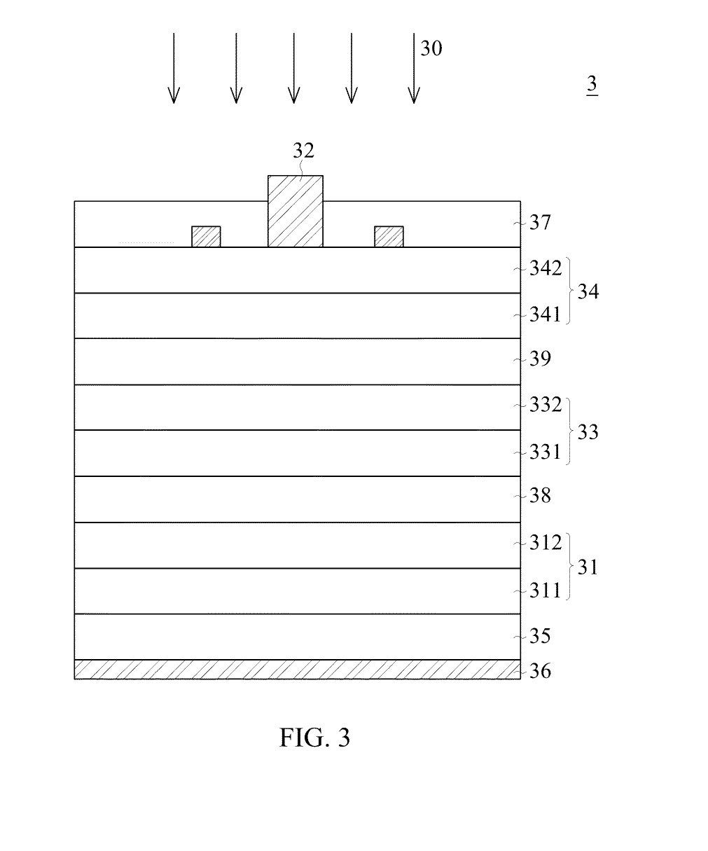

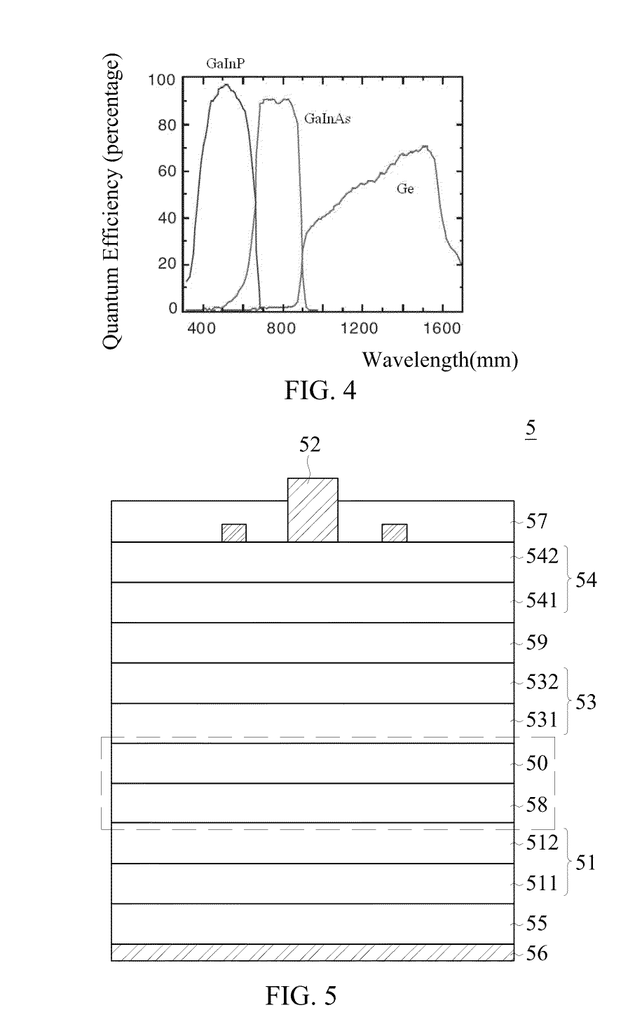

### DETAILED DESCRIPTION OF PREFERRED EMBODIMENTS

The embodiments are described hereinafter in accompany with drawings.

FIG. 5 shows a multi junction tandem solar cell device 5 in accordance with one embodiment of the disclosure. The structure of the multi junction tandem solar cell device 5 from bottom to top is tandem formed by a second electrode 56, a Ge substrate 55, a Ge series first subcell 51, a GaInAs series second subcell 53, a GaInP series third subcell 54, and a first electrode 52. Wherein, each subcell comprises a p-n junction composed of a p-type semiconductor material layer and an n-type semiconductor material layer. Accordingly, the first subcell 51 comprises a first p-n junction composed of a p-type Ge semiconductor material layer 511 and an n-type Ge semiconductor material layer 512; the second subcell 53 comprises a second p-n junction composed of a p-type GaInAs semiconductor material layer 531 and an n-type GaInAs semiconductor material layer 532; the third subcell 54 comprises a third p-n junction composed of a p-type GaInP semiconductor material layer 541 and an n-type GaInP semiconductor material layer 542. The lattice constant of the Ge substrate 55 and the Ge first subcell 51 is 5.658 A, so the structure is lattice matched. However, the lattice constant of the second subcell 53 (GaInAs) is about 5.722 A, and the lattice constant of the third subcell 54 (GaInP) is about 5.722 A. Compared with the Ge first subcell 51, the difference of the lattice constant between the adjacent second subcell 53 is [(5.722−5.6580)/5.658]×100%≈1.13%, which is lattice mismatched.

Besides, a first tunnel junction 58 could be optionally formed between the first subcell 51 and the second subcell 53, and a second tunnel junction 59 could be optionally formed between the second subcell 53 and the third subcell 54. The tunnel junction could be formed optionally between the subcells to adjust the reverse bias voltage resistance between two adjacent subcells, to reduce the charges accumulated at one side of the two adjacent subcells, and to match the currents between the subcells. The structure of the tunnel junction is generally the highly doped p-type or n-type semiconductor layer, and the material of the tunnel junction has a band gap not smaller than that of the subcell which has a smaller band gap in the two adjacent subcells. Preferably, the band gap of the material of the tunnel junction is not smaller than that of the subcell having the larger band gap in the two adjacent subcells. Therefore, to the solar spectrum left from passing the subcells, the tunnel junction is transparent structure, and the remaining solar spectrum could be absorbed by other subcells. In this embodiment, in order to achieve the higher optoelectronic converting efficiency, an anti-reflective layer 57 could be optionally formed between the electrode 52 and the third subcell 54 to reduce the light reflection from the structure surface.

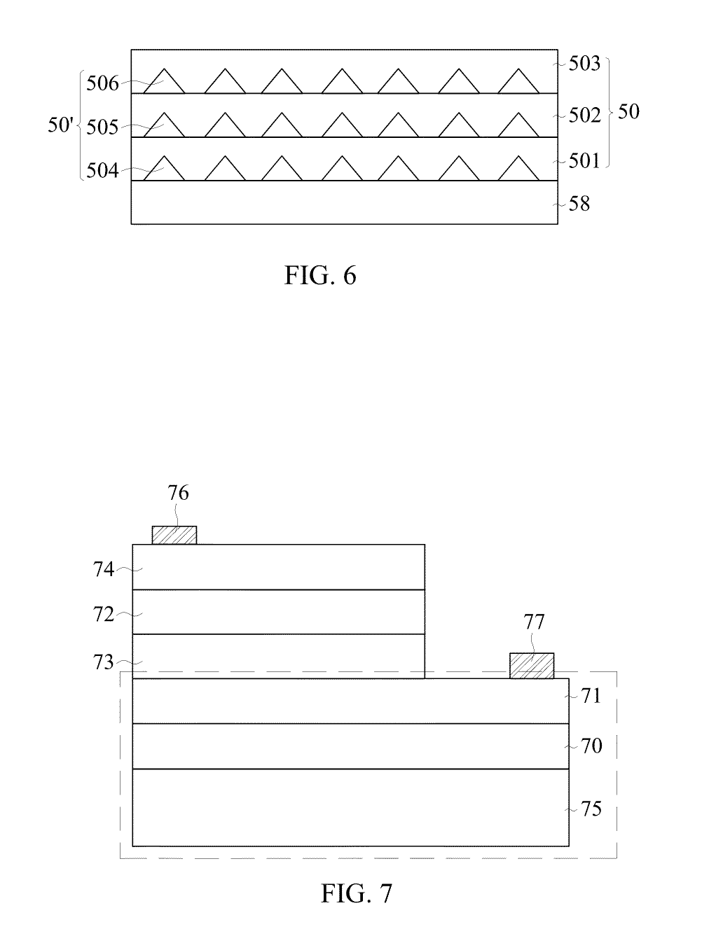

In this embodiment, in order to reduce the stress which leads to the epitaxial defects, a semiconductor buffer layer combination 50 is added between the first subcell 51 and the second subcell 53. The detail of the semiconductor buffer layer combination 50 and the first tunnel junction 58 (shown as the dotted line in the figure) thereunder is shown in FIG. 6. The semiconductor buffer layer combination 50 includes three semiconductor buffer layers 501, 502, and 503. Along the direction from the side close to the first subcell 51 to the side close to the second subcell 53, the lattice constant of the first semiconductor buffer layer 501, the second semiconductor layer 502, and the third semiconductor layer 503 increases from the value smaller and close to the lattice constant 5.658 of the first subcell 51 to the value smaller and close to the lattice constant 5.722 of the second subcell 53. That is, the composition, such as the lattice constant and/or the ratio of the material composition changes along a single direction. Take the embodiment for example, the composition of the three semiconductor buffer layers could be GaₓIn₁₋ₓAs, which is similar to the epitaxial composition of the second subcell 53, and the lattice constant value could be further changed by adjusting the ratio of the Ga element and the In element in the GaₓIn₁₋ₓAs semiconductor structure.

Besides, in this embodiment, a plurality of InAs quantum dots are further formed between each adjacent semiconductor buffer layers to make the semiconductor buffer layer have a patterned surface. The manufacturing procedures are shown as the following: after forming a first quantum dot layer 504 including a plurality of AsIn quantum dots on the first tunnel junction 58, forming a first semiconductor buffer layer 501; after forming a second quantum dot layer 505 including a plurality of AsIn quantum dots on the first semiconductor buffer layer 501, forming a second semiconductor buffer layer 502; after forming a third quantum dot layer 506 including a plurality of AsIn quantum dots on the second semiconductor buffer layer 502, forming a third semiconductor buffer layer 503; finally, forming the p-type GaInAs semiconductor material layer 531 and the semiconductor epitaxial stack layers thereon. Wherein, the quantum dot layer combination could be formed by the conventional method such as Metal-Organic Chemical Vapour Deposition (MOCVD), Molecular Beam Epitaxy (MBE), Liquid Phase Epitaxy (LPE), and Gas Phase Epitaxy (VPE).

Noticeably, while forming the quantum dots, because the quantum dot itself lacks of the crystal defects, it could terminate the upward extension of the defects from the lower epitaxial layer. Besides, by selecting different materials of the quantum dots and the semiconductor buffer layers, the growth stress of the epitaxial layer structure could also be released and the formation of the epitaxial defects could also be reduced. Take the present embodiment for example, by combining the InAs quantum dot layer 50′ having a larger lattice constant and the Ge substrate 55 having a smaller lattice constant, to the GaₓIn₁₋ₓAs semiconductor buffer layer combination 50, because the two different materials have different stresses, the stresses could be balanced and eliminated mutually. Therefore, by adjusting the composition, the quality of the epitaxial structure could be improved.

Next, please refer to FIG. 7, FIG. 7 shows a light-emitting diode device 7 in accordance with another embodiment of the present application. The main structure from bottom to top is tandemly formed by a substrate 75, a first semiconductor material layer 71, an optoelectronic conversion layer 73, and a second semiconductor material layer 72. A first electrode 77 is formed on the first semiconductor material layer 71, and a second electrode 76 is formed on the second semiconductor material layer 72. Besides, a transparent conductive layer 74 could be further optionally formed on the second semiconductor material layer 72 in order to increase the light extraction efficiency and the current diffusion efficiency.

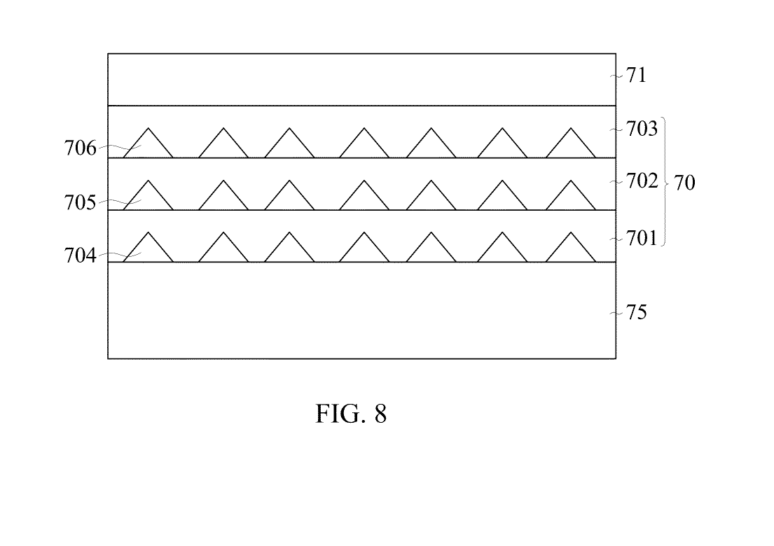

In this embodiment, when the lattice constant of the substrate 75 is mismatched with that of the first semiconductor material layer 71, in order to reduce the formation of the epitaxial defects arisen from the formation of the stress, a semiconductor buffer layer combination 70 could be added between the substrate 75 and the first semiconductor material layer 71. The detail of the semiconductor buffer layer combination 70, the adjacent substrate 75, and the first semiconductor material layer 71 is shown in FIG. 8, the semiconductor buffer layer combination 70 includes three semiconductor buffer layers 701, 702, and 703. Along the direction from the side close to the substrate 75 to the side close to the first semiconductor material layer 71, the lattice constant of the first semiconductor buffer layer 701, the second semiconductor layer 702, and the third semiconductor layer 703 increases from the value close to the lattice constant of the substrate 75 to the value close to the lattice constant of the first semiconductor material layer 71. That is, the composition, such as the lattice constant and/or the ratio of the material composition changes along a single direction. Similar to the former embodiment, the composition of the three semiconductor buffer layers could be the same as the composition of the first semiconductor material layer 71, and the lattice constant could be changed by adjusting the relative ratio of the elements in the composition. Of course, the composition could also be different from the composition of the first semiconductor material layer 71, and the lattice constant could be adjusted by selecting different elements composing the epitaxial layers.

Besides, in this embodiment, a plurality of quantum dots are further formed between each adjacent semiconductor buffer layers to make the semiconductor buffer layer have a patterned surface. The manufacturing procedures are shown as the following: after forming a first quantum dot layer 704 including a plurality of quantum dots on the substrate 75, forming a first semiconductor buffer layer 701; after forming a second quantum dot layer 705 including a plurality of quantum dots on the first semiconductor buffer layer 701, forming a second semiconductor buffer layer 702; after forming a third quantum dot layer 706 including a plurality of quantum dots on the second semiconductor buffer layer 702, forming a third semiconductor buffer layer 73; finally, forming the first semiconductor material layer 71 and the semiconductor epitaxial stack layers thereon. Wherein, the quantum dot layer combination could be formed by the conventional method such as Metal-Organic Chemical Vapour Deposition (MOCVD), Molecular Beam Epitaxy (MBE), Liquid Phase Epitaxy (LPE), and Gas Phase Epitaxy (VPE).

Noticeably, while forming the quantum dots, because the quantum dot itself lacks of the crystal defects, it could terminate the upward extension of the defects from the lower epitaxial layer. Besides, by selecting different materials of the quantum dots and the semiconductor buffer layers, the growth stress of the epitaxial layer structure could also be released and the formation of the epitaxial defects could also be reduced. Take the present embodiment for example, by combining the quantum dot layers with different lattice constants and the semiconductor buffer layer combination 70, because the quantum dot layers and the substrate 75 have different lattice constants, and the quantum dot layers and the substrate 75 have different stresses, the stresses could be balanced and eliminated mutually. Therefore, by adjusting the composition, the quality of the epitaxial structure could be improved.

As shown in the embodiments above, the material of the substrate of the semiconductor epitaxial structure could be but is not limited to the semiconductor material such as GaAs, Ge, SiC, Si, InP, SiGe, ZnO, GaN, and it also could be the metal material or the transparent material such as glass.

Noticeably, the person with ordinary skill in the art could realize that the present invention could be but not limited to the specific kinds of devices shown as the embodiments above such as the multi junction tandem solar cell device and the light-emitting diode device, it could be suitable for any semiconductor epitaxial structure with the lattice constant mismatch to release the stress, to reduce the formation of the epitaxial defects, and to increase the quality of the epitaxial structure. Besides, the patterned semiconductor buffer layer surface is also not limited to be formed by formation of a plurality of the quantum dots, and the semiconductor buffer layer surface could also be patterned by etching, laser sculpturing, or depositing. With the patterned surface, it also achieves the stress released effect. Of course, the number of the semiconductor buffer layers and the quantum dot layers could also be adjusted depends on the suitable situation.

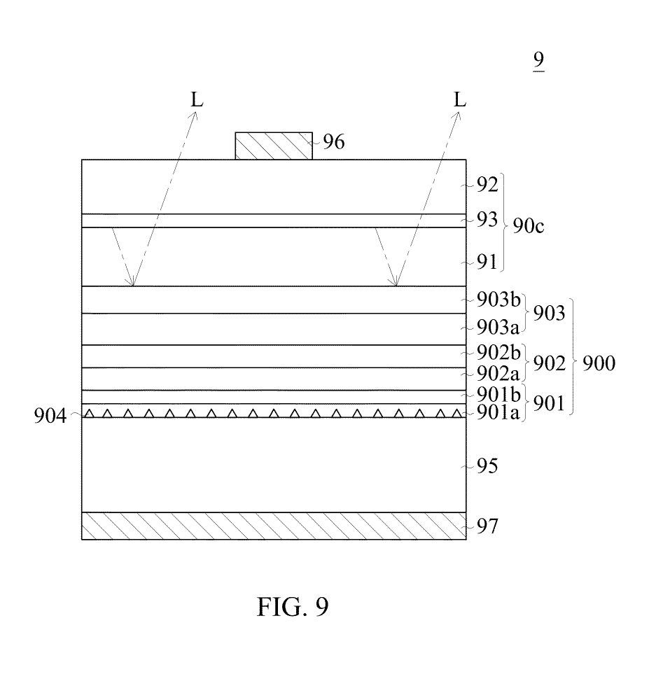

FIG. 9 shows an optoelectronic device being a light-emitting diode device in accordance with another embodiment of the present application. The light-emitting diode device 9 comprises a substrate 95 and a converting structure 90c over the substrate 95. The converting structure 90c converts electrical current into light. The converting structure 90c comprises a first semiconductor cladding layer 91, an active layer 93, and a second semiconductor cladding layer 92. The first semiconductor cladding layer 91 and the second semiconductor cladding layer 92 are of different conductive types and have higher energy band gap than the active layer 93 for confining carriers, e.g. electrons or holes, within the active layer 93. For example, the first semiconductor cladding layer 91 is an n-type semiconductor layer, and the second semiconductor cladding layer 92 is a p-type semiconductor layer. The first semiconductor cladding layer 91, the active layer 93, and the second semiconductor cladding layer 92 comprise III-V group material. A first electrode 96 is disposed on the second semiconductor cladding layer 92, and a second electrode 97 is disposed on the substrate 95.

When the lattice constant of the substrate 95 is mismatched with that of the converting structure 90c or the first semiconductor cladding layer 91, a semiconductor buffer layer combination 900 is formed between the substrate 95 and the converting structure 90c for reducing the formation of the epitaxial defects during epitaxially growing the converting structure 90c on the substrate 95. The semiconductor buffer layer combination 900 comprises multiple first semiconductor layers 901a, 902a, 903a and multiple second semiconductor layers 901b, 902b, 903b alternately stacked, wherein each of the multiple first semiconductor layers 901a, 902a, 903a comprises a first element, each of the multiple second semiconductor layers 901b, 902b, 903b comprises a second element different from the first element, and the composition ratio of the first element gradually increases or decreases with an increase of the distance between the first semiconductor layers 901a, 902a, 903a and the substrate 95. In addition, the composition ratio of the second element gradually increases or decreases with an increase of the distance between the second semiconductor layers 901b, 902b, 903b and the substrate 95. For example, the substrate 95 comprises GaAs and the converting structure 90c comprises InₐGa₍₁₋ₐ₎As (0<a<0.5) to emit light with a wavelength of about 880˜1400 nm. Specifically, the active layer 93 of the converting structure 90c comprises In_{0.38}Ga_{0.62}As for emitting light with a wavelength of about 1216 nm. Since the lattice constant of GaAs is about 5.653 Å whereas the lattice constant of In_{0.38}Ga_{0.62}As is about 5.8 Å, the lattice constant of the substrate 95 is mismatched with that of the converting structure 90c. It is noted that it is generally considered “mismatched” when the difference of the lattice constants between two layers is over 0.05%, and “matched” when the difference of the lattice constants between two layers is less than 0.05%. Therefore, the semiconductor buffer layer combination 900 is formed between the substrate 95 and the converting structure 90c.

The first semiconductor layers 901a, 902a, 903a comprise GaₓIn₁₋ₓP, and the second semiconductor layers 901b, 902b, 903b comprise Al_{y}In_{1-y}P, wherein 0.1<x, y<0.6. The first element in the first semiconductor layers 901a, 902a, 903a is gallium (Ga), and the second element in the second semiconductor layers 901b, 902b, 903b is aluminum (Al). The composition ratio of the first element, i.e. gallium, gradually decreases with an increase of the distance between the first semiconductor layers 901a, 902a, 903a and the substrate 95. For example, x in GaₓIn₁₋ₓP is 0.49, 0.3, and 0.14 for the first semiconductor layers 901a, 902a, and 903a, respectively. In addition, the composition ratio of the second element, i.e. aluminum, gradually decreases with the distance between the second semiconductor layers 901b, 902b, 903b and the substrate 95. For example, y in Al_{y}In_{1-y}P is 0.49, 0.3, and 0.14 for the second semiconductor layers 901b, 902b, and 903b, respectively. In the present embodiment, a lattice constant of the first semiconductor layer closest to the substrate 95, i.e. the first semiconductor layers 901a, is substantially matched to the lattice constant of the substrate 95. For example, the first semiconductor layers 901a which comprises Ga_{0.49}In_{0.51}P has a lattice constant of about 5.653 Å, which is substantially matched to the lattice constant of the substrate 95. In addition, a lattice constant of the second semiconductor layer closest to the converting structure 90c, i.e. the second semiconductor layers 903b, is substantially matched to the lattice constant of the converting structure 90c. For example, the second semiconductor layers 903b which comprises Al_{0.14}In_{0.86}P has a lattice constant of about 5.8 Å, which is substantially matched to the lattice constant of the converting structure 90c. It is noted that although only three pairs of alternately laminated first and second semiconductor layers are illustrated in the present embodiment, the person of ordinary skill of the art can increase the number of the first/second semiconductor layers so that the composition ratio of the first element or the second element increases or decreases smoothly with a smoother lattice transition, and the stress and the epitaxial defects can be significantly reduced. As previous illustration, a plurality of quantum dots 904 can be optionally formed between the substrate 95 and the semiconductor buffer layer combination 900 to stop the dislocation defects extending into the converting structure 90c.

In the present embodiment, the first semiconductor layers 901a, 902a, 903a and the second semiconductor layers 901b, 902b, 903b are alternately laminated to form a

DBR (Distributed Bragg Reflector) structure. For example, the first semiconductor layer 901a which comprises Ga_{0.49}In_{0.51}P and the second semiconductor layers 901b which comprises Al_{0.49}In_{0.51}P are paired to be one pair 901. Similarly, the first semiconductor layer 902a and the second semiconductor layers 902b are paired to be one pair 902, and the first semiconductor layer 903a and the second semiconductor layers 903b are paired to be one pair 903. The stack of the pair 901, pair 902, and pair 903 forms the DBR structure to reflect light emitted from the converting structure 90c. The DBR structure has a different reflectivity depending on a number of pairs, and is in a range of 50%˜99%, and preferred greater than 70% for the light emitted by the active layer 93. In other words, in addition to the function to reduce the stress and the epitaxial defects in the light-emitting diode device 9, the semiconductor buffer layer combination 900 can be a DBR structure. It is noted that since the composition ratio of the first element gradually increases or decreases with an increase of the distance between the first semiconductor layers 901a, 902a, 903a and the substrate 95, the indices of refraction of the first semiconductor layers 901a, 902a, 903a gradually change accordingly. In addition, an optical path length (OPL) is the product of the index of refraction of the medium through which light propagates and the geometric length of the path through which light propagates. Therefore, to meet the requirement that an optical thickness of layer in a DBR structure is close one quarter wavelength of light to be reflected, a thickness of the first semiconductor layers 901a, 902a, 903a gradually increases or decreases with an increase of the distance between the first semiconductor layers 901a, 902a, 903a and the substrate 95. In the present embodiment, the thickness of the first semiconductor layers 901a, 902a, 903a gradually increases with an increase of the distance between the first semiconductor layers 901a, 902a, 903a and the substrate 95. Similarly, a thickness of the second semiconductor layers 901b, 902b, 903b also gradually increases or decreases with an increase of the distance between the second semiconductor layers 901b, 902b, 903b and the substrate 95. In the present embodiment, the thickness of the second semiconductor layers 901b, 902b, 903b also gradually increases with an increase of the distance between the second semiconductor layers 901b, 902b, 903b and the substrate 95.

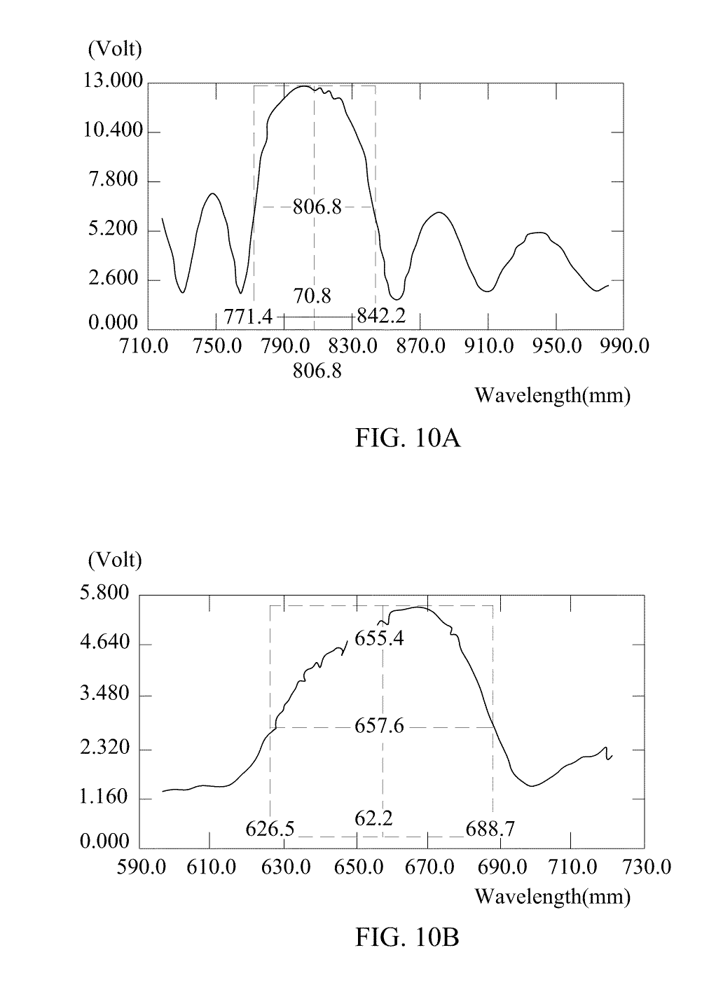

FIG. 10A shows a spectrum of a reflectivity of the semiconductor buffer layer combination 900 according to the embodiment described in FIG. 9, wherein semiconductor buffer layer combination 900 being a DBR structure having a maximum reflectivity at the light wavelength around 807 nm, and having a higher reflectivity at the light wavelength from 790 nm to 830 nm. The horizontal axis stands for the wavelength of reflected light, and the vertical axis stands for the signal strength in voltage which is in proportion to light intensity. Specifically, the semiconductor buffer layer combination 900 is formed on a GaAs substrate with ten pairs of alternating stacked first semiconductor layers and second semiconductor layers, wherein the first semiconductor layer comprises GaₓIn₁₋ₓP and the second semiconductor layer comprises Al_{y}In_{1-y}P wherein 0.2<x, y<0.5.

Similarly, FIG. 10B shows a spectrum of a reflectivity of the semiconductor buffer layer combination 900 according to another embodiment described in FIG. 9, wherein the semiconductor buffer layer combination 900 being a DBR structure having a maximum reflectivity at the light wavelength around 670 nm, and having a higher reflectivity at the light wavelength from 630 nm to 690 nm. The horizontal axis stands for the wavelength of reflected light, and the vertical axis stands for the signal strength in voltage which is in proportion to light intensity. Specifically, the semiconductor buffer layer combination 900 is formed on a GaAs substrate with ten pairs of alternating stacked first semiconductor layers and second semiconductor layers, wherein the first semiconductor layer comprises GaₓIn₁₋ₓP and the second semiconductor layer comprises Al_{y}In_{1-y}P wherein 0.22<x, y<0.5.

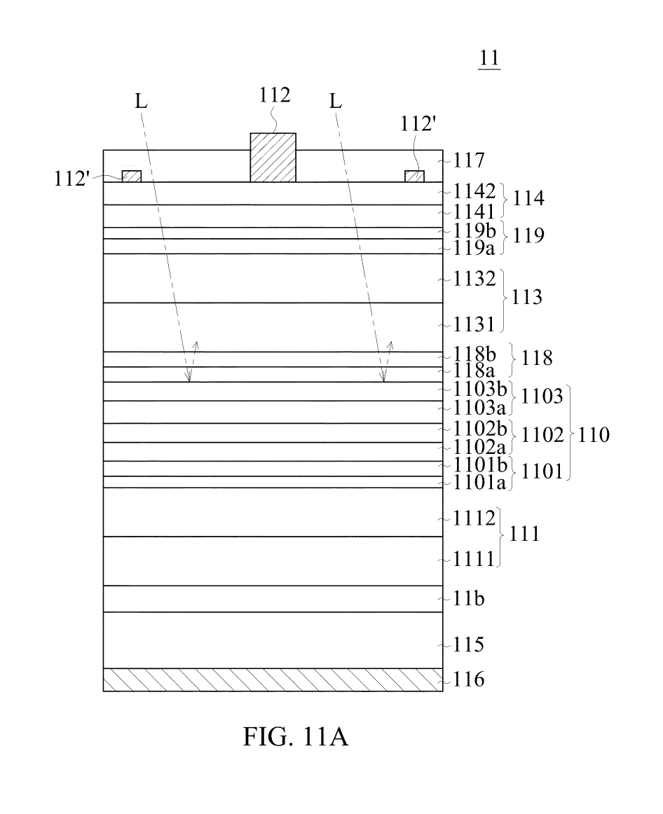

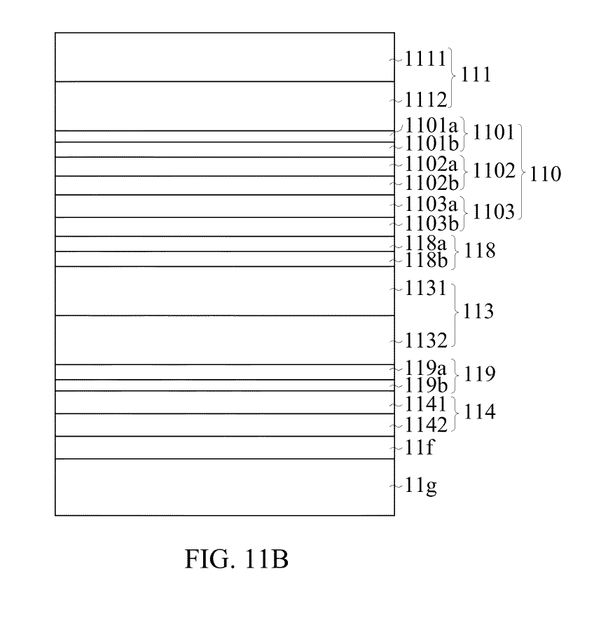

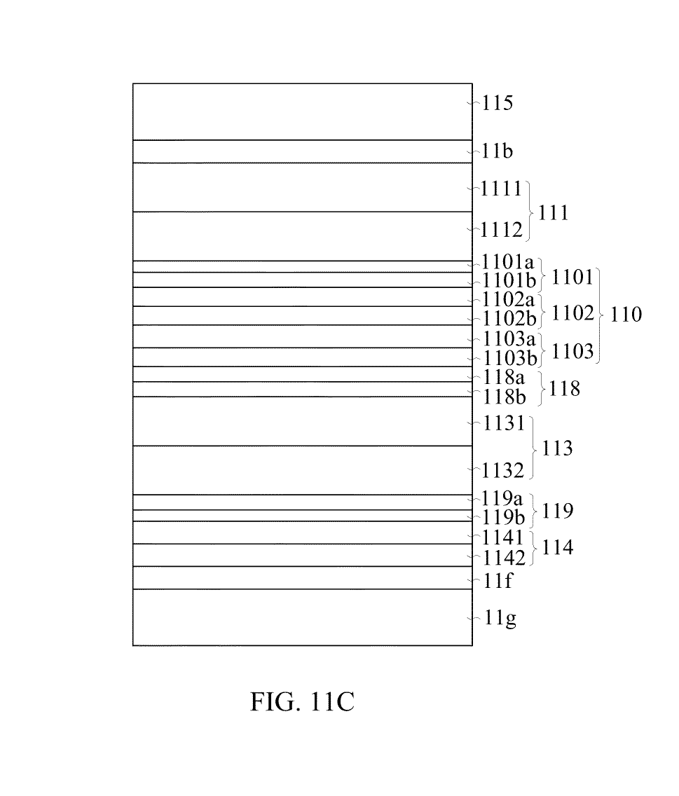

FIG. 11A shows an optoelectronic device being a multi junction solar cell device in accordance with another embodiment of the present application. FIGS. 11B to 11C show the process to form the optoelectronic device in FIG. 11A. As shown in FIG. 11A, the solar cell device 11 comprises a substrate 115, e.g. Si substrate. A bonding layer 11b is on the substrate 115. The bonding layer 11b comprises gold (Au), indium (In) or an alloy thereof. A converting structure 111 is on the bonding layer 11b. The converting structure 111 is bonded to the substrate 115 through the bonding layer 1 lb. The converting structure 111 converts light into electrical current. The converting structure 111 comprises a first semiconductor converting layer 1111 and a second semiconductor converting layer 1112, wherein the first semiconductor converting layer 1111 and the second semiconductor converting layer 1112 are of different conductive types to form a p-n junction for converting light into electrical current. For example, the converting structure 111 comprises the first semiconductor converting layer 1111 of p-type In_{0.3}Ga_{0.7}As and the second semiconductor converting layer 1112 of n-type In_{0.3}Ga_{0.7}As. The converting structure 111 forms an InGaAs-based bottom solar subcell which absorbs light with a wavelength substantially longer than 880 nm or preferred between 880 nm and 1300 nm and converts it to electrical current. A semiconductor buffer layer combination 110 is on the converting structure 111. The semiconductor buffer layer combination 110 comprises multiple first semiconductor layers 1101a, 1102a, 1103a and multiple second semiconductor layers 1101b, 1102b, 1103b alternately stacked. Each of the multiple first semiconductor layers 1101a, 1102a, 1103a comprises a first element, each of the multiple second semiconductor layers 1101b, 1102b, 1103b comprises a second element different from the first element, and the composition ratio of the first element gradually increases or decreases with an increase of the distance between the first semiconductor layers 1101a, 1102a, 1103a and the substrate 115. In addition, the composition ratio of the second element gradually increases or decreases with an increase of the distance between the second semiconductor layers 1101b, 1102b, 1103b and the substrate 115. For example, the first semiconductor layers 1101a, 1102a, 1103a comprise GaₓIn₁₋ₓP, and the second semiconductor layers 1101b, 1102b, 1103b comprise Al_{y}In_{1-y}P, wherein 0.1<x, y<0.6. The first element in the first semiconductor layers 1101a, 1102a, 1103a is gallium (Ga), and the second element in the second semiconductor layers 1101b, 1102b, 1103b is aluminum (Al). The composition ratio of the first element, i.e. gallium, gradually increases with the distance between the first semiconductor layer 1101a, 1102a, 1103a and the substrate 115. For example, x in GaₓIn₁₋ₓP is 0.14, 0.3, and 0.49 for the first semiconductor layers 1101a, 1102a, and 1103a, respectively. In addition, the composition ratio of the second element, i.e. aluminum, gradually increases with the distance between the second semiconductor layers 1101b, 1102b, 1103b and the substrate 115. For example, y in Al_{y}In_{1-y}P is 0.14, 0.3, and 0.49 for the second semiconductor layers 1101b, 1102b, and 1103b, respectively. In the present embodiment, the first semiconductor layers 1101a, 1102a, 1103a and the second semiconductor layers 1101b, 1102b, 1103b are alternately laminated to form a DBR (Distributed Bragg Reflector) structure. For example, the first semiconductor layer 1101a and the second semiconductor layers 1101b are paired to be one pair 1101. Similarly, the first semiconductor layer 1102a and the second semiconductor layers 1102b are paired to be one pair 1102, and the first semiconductor layer 1103a and the second semiconductor layers 1103b are paired to be one pair 1103. The stack of the pair 1101, pair 1102, and pair 1103 forms the DBR structure to reflect light incident into the solar cell device 11 which is not absorbed by converting structures 114, 113. A tunneling diode 118 is on the semiconductor buffer layer combination 110. The tunneling diode 118 comprises a first layer 118a and a second layer 118b, wherein the first layer 118a and the second layer 118b are of different conductive types to form a p-n junction for electrically connecting the converting structure 111 to a converting structure 113. For example, the first layer 118a is heavily doped n-type GaAs and the second layer 118b is heavily doped p-type AlₓGa₁₋ₓAs (0<x<1) when the converting structure 111 comprises the first semiconductor converting layer 1111 of p-type and the second semiconductor converting layer 1112 of n-type. The converting structure 113 is on the tunneling diode 118 for converting light into electrical current. The converting structure 113 comprises a first semiconductor converting layer 1131 and a second semiconductor converting layer 1132, wherein the first semiconductor converting layer 1131 and the second semiconductor converting layer 1132 are of different conductive types to form a p-n junction for converting light into electrical current. For example, the converting structure 113 comprises the first semiconductor converting layer 1131 of p-type GaAs and the second semiconductor converting layer 1132 of n-type GaAs. The converting structure 113 forms a GaAs middle solar subcell which absorbs light with a wavelength substantially between 650 nm and 880 nm and converts it to electrical current. A tunneling diode 119 is on the converting structure 113. The tunneling diode 119 comprises a first layer 119a and a second layer 119b, wherein the first layer 119a and the second layer 119b are of different conductive types to form a p-n junction for electrically connecting the converting structure 113 to a converting structure 114. For example, the first layer 119a is heavily doped n-type and the second layer 119b is heavily doped p-type when the converting structure 113 comprises the first semiconductor converting layer 1131 of p-type and the second semiconductor converting layer 1132 of n-type. A converting structure 114 is on the tunneling diode 119. The converting structure 114 converts light into electrical current. The converting structure 114 comprises a first semiconductor converting layer 1141 and a second semiconductor converting layer 1142, wherein the first semiconductor converting layer 1141 and the second semiconductor converting layer 1142 are of different conductive types to form a p-n junction for converting light into electrical current. For example, the converting structure 114 comprises the first semiconductor converting layer 1141 of p-type GaₓIn₁₋ₓP (0<x<1) and the second semiconductor converting layer 1142 of n-type GaₓIn₁₋ₓP (0<x<1). The converting structure 114 forms a GaInP-based top solar subcell which absorbs light with a wavelength substantially shorter than 650 nm and converts it to electrical current. A first electrode 112 and its extending fingers 112′ is on the converting structure 114 for conducting current through external power device. An anti-reflective layer 117 is on the converting structure 114 and exposes the first electrode 112. A second electrode 116 is under the substrate 115 for conducting current through external power device. FIGS. 11B to 11C show the process for forming the solar cell device 11 in FIG. 11A. As shown in FIG. 11B, the process forming the solar cell device 11 comprises providing a growth substrate 11g, e.g., a GaAs substrate. Then a buffer layer 11f, such as a layer comprising GaAs, is formed on the growth substrate 11g. Next, the converting structure 114 is formed on the buffer layer 11f. The second semiconductor converting layer 1142 of the converting structure 114 comprises GaₓIn₁₋ₓP (0<x<1) which is doped with Si (Silicon) to form n-type. The first semiconductor converting layer 1141 of the converting structure 114 comprises GaₓIn₁₋ₓP (0<x<1) which is doped with Zn (Zinc) to form p-type. The converting structure 114 forms a GaInP-based top solar subcell which absorbs light with a wavelength substantially shorter than 650 nm and converts it to electrical current. Next, the tunneling diode 119 is formed on the converting structure 114. The second layer 119b of the tunneling diode 119 comprises AlₓGa₁₋ₓAs (0<x<1) which is heavily doped with C (Carbon) to form p-type. The first layer 119a of the tunneling diode 119 comprises GaₓIn₁₋ₓP (0<x<1) which is heavily doped with Te (Tellurium) to form n-type. The doping concentration in the first layer 119a and the second layer 119b is substantially greater than 1*10¹⁹/cm³. It is noted that “heavily doped” means the doping concentration in the doped layer is greater than 1*10¹⁹/cm³.

Next, the converting structure 113 is formed on the tunneling diode 119. The second semiconductor converting layer 1132 of the converting structure 113 comprises GaAs which is doped with Si (Silicon) to form n-type. The first semiconductor converting layer 1131 of the converting structure 113 comprises GaAs which is doped with Zn (Zinc) to form p-type. The converting structure 113 forms a GaAs middle solar subcell which absorbs light with a wavelength substantially between 650 nm and 880 nm and converts it to electrical current. Next, the tunneling diode 118 is formed on the converting structure 113. The second layer 118b of the tunneling diode 118 comprises AlₓGa₁₋ₓAs (0<x<1) which is heavily doped with C (Carbon) to form p-type. The first layer 118a of the tunneling diode 118 comprises GaAs which is heavily doped with Te (Tellurium) to form n-type. It is noted that in an alternative embodiment, the tunneling diode 118 may be formed between the semiconductor buffer layer combination 110 and the converting structure 111 with other material for lattice match consideration.

Next, before the formation of the converting structure 111, a semiconductor buffer layer combination 110 is formed on the between the converting structure 111 and the converting structure 113. because the converting structure 111 comprises InₓGa₁₋ₓAs (0<x<1) material, and the lattice constant of the InₓGa₁₋ₓAs (0<x<1) material is mismatched with that of the converting structure 113 or the first layer 118a of the tunneling diode 118, in order to reduce formation of the epitaxial defects during epitaxially grown the converting structure 111, The semiconductor buffer layer combination 110 comprises multiple first semiconductor layers 1101a, 1102a, 1103a and multiple second semiconductor layers 1101b, 1102b, 1103b alternately stacked, wherein each of the multiple first semiconductor layers 1101a, 1102a, 1103a comprises a first element, each of the multiple second semiconductor layers 1101b, 1102b, 1103b comprises a second element different from the first element, and the composition ratio of the first element gradually increases or decreases with an increase of the distance between the first semiconductor layers 1101a, 1102a, 1103a and the growth substrate 11g. In addition, the composition ratio of the second element gradually increases or decreases an increase of with the distance between the second semiconductor layers 1101b, 1102b, 1103b and the growth substrate 11g. For example, the converting structure 113 comprises GaAs and the converting structure 111 comprises InₓGa₁₋ₓAs (0<x<1) material. The lattice constant of GaAs is about 5.653 Å while the lattice constant of InₐGa₍₁₋ₐ₎As (0<a<1) material of the converting structure 111 is about 5.8 Å. Because the lattice constant of the converting structure 113 is mismatched with that of the converting structure 111, the semiconductor buffer layer combination 110 is added between the converting structure 113 and the converting structure 111. The first semiconductor layers 1101a, 1102a, 1103a comprise GaₓIn₁₋ₓP, and the second semiconductor layers 1101b, 1102b, 1103b comprise Al_{y}In_{1-y}P, wherein 0.1<x, y<0.6. The first element in the first semiconductor layers 1101a, 1102a, 1103a is gallium (Ga), and the second element in the second semiconductor layers 1101b, 1102b, 1103b is aluminum (Al). The composition ratio of the first element, i.e. gallium, gradually decreases with the distance between the first semiconductor layer 1101a, 1102a, 1103a and the growth substrate 11g. For example, x in GaₓIn₁₋ₓP is 0.14, 0.3, and 0.49 for the first semiconductor layers 1101a, 1102a, and 1103a, respectively. In addition, the composition ratio of the second element, i.e. aluminum, gradually decreases with the distance between the second semiconductor layers 1101b, 1102b, 1103b and the growth substrate 11g. For example, y in Al_{y}In_{1-y}P is 0.14, 0.3, and 0.49 for the second semiconductor layers 1101b, 1102b, and 1103b, respectively. In the present embodiment, a lattice constant of the second semiconductor layer closest to the converting structure 113, i.e. the second semiconductor layers 1103b, is substantially matched to the lattice constant of the converting structure 113. For example, the second semiconductor layers 1103b which comprises Al_{0.49}In_{0.51}P has a lattice constant of about 5.653 Å, which is substantially matched to the lattice constant of the converting structure 113. In addition, a lattice constant of the first semiconductor layer closest to the converting structure 111, i.e. the first semiconductor layers 1101a, is substantially matched to the lattice constant of the converting structure 111. For example, the first semiconductor layers 1101a which comprises Ga_{0.14}In_{0.86}P has a lattice constant of about 5.8 Å, which is substantially matched to the lattice constant of the converting structure 111. It is noted that although only three pairs of alternately laminated first and second semiconductor layers are illustrated in the present embodiment, the person of ordinary skill of the art can increase the number of the first/second semiconductor layers so that the composition ratio of the first element or the second element increases or decreases smoothly with a smoother lattice transition, and the stress and the epitaxial defects can be significantly reduced.

In the present embodiment, the first semiconductor layers 1101a, 1102a, 1103a and the second semiconductor layers 1101b, 1102b, 1103b are alternately laminated to form a DBR (Distributed Bragg Reflector) structure. For example, the first semiconductor layer 1101a which comprises Ga_{0.14}In_{0.86}P and the second semiconductor layers 1101b which comprises Al_{0.14}In_{0.86}P are paired to be one pair 1101. Similarly, the first semiconductor layer 1102a and the second semiconductor layers 1102b are paired to be one pair 1102, and the first semiconductor layer 1103a and the second semiconductor layers 1103b are paired to be one pair 1103. The stack of the pair 1101, pair 1102, and pair 1103 forms the DBR structure to reflect light incident into the solar cell device 11 which is not absorbed by the converting structure 114, 113. In other words, in addition to the function to reduce the stress and the epitaxial defects in the solar cell device 11, the semiconductor buffer layer combination 110 can be a DBR structure. The DBR structure has a different reflectivity value depending on a number of pairs, and is in a range of 50%-99%, and preferred greater than 70%. It is noted that since the composition ratio of the first element gradually increases or decreases with an increase of the distance between the first semiconductor layer 1101a, 1102a, 1103a and the growth substrate 11g, the indices of refraction of the first semiconductor layers 1101a, 1102a, 1103a gradually change accordingly. In addition, an optical path length (OPL) is the product of the index of refraction of the medium through which light propagates and the geometric length of the path through which light propagates. Therefore, to meet the requirement that an optical thickness of layer in a DBR structure is close one quarter the wavelength of light to be reflected, a thickness of the first semiconductor layers 1101a, 1102a, 1103a gradually decreases with the distance between the first semiconductor layers 1101a, 1102a, 1103a and the growth substrate 11g. Similarly, a thickness of the second semiconductor layers 1101b, 1102b, 1103b also gradually decreases with the distance between the second semiconductor layers 1101b, 1102b, 1103b and the growth substrate 11g.

After formation of the semiconductor buffer layer combination 110, the converting structure 111 is formed on the semiconductor buffer layer combination 110. The second semiconductor converting layer 1112 of the converting structure 111 comprises InₓGa₁₋ₓAs (0<x<1) which is doped with Si (Silicon) to form n-type. The first semiconductor converting layer 1111 of the converting structure 111 comprises InₓGa₁₋ₓAs (0<x<1) which is doped with Zn (Zinc) to form p-type. In the present embodiment, both the first semiconductor converting layer 1111 and the second semiconductor converting layer 1112 of the converting structure 111 comprise In_{0.3}Ga_{0.7}As. The converting structure 111 forms an InGaAs-based bottom solar subcell which absorbs light with a wavelength substantially longer than 880 nm or between 880 nm and 1300 nm and converts it to electrical current.

Next, as shown in FIG. 11C, the process for forming the solar cell device 11 further comprises providing the substrate 115 and bonding the substrate 115 to the converting structure 111 through the bonding layer 11b. The substrate 115 is a conductive substrate, such as a Si substrate. In one embodiment, a first bonding layer (not shown) and a second bonding layer (not shown) are firstly formed on the substrate 115 and the converting structure 111 respectively, and then bonded together to form the bonding layer 11b. The first bonding layer and the second bonding layer comprise gold (Au), indium (In) or an alloy thereof. After bonding, the growth substrate 11g and the buffer layer 11f are removed to expose the converting structure 114. Then, the first electrode 112 and its extending fingers 112′ is formed on the converting structure 114, and the anti-reflective layer 117 is formed on the converting structure 114. The second electrode 116 is formed on the substrate 115 to form the solar cell device 11 as shown in FIG. 11A.

The foregoing description has been directed to the specific embodiments of this disclosure. It is apparent; however, that other alternatives and modifications may be made to the embodiments without escaping the spirit and scope of the disclosure.

What is claimed is:

1. An optoelectronic device comprising:
a substrate;
a converting structure for converting energy between light and electric current; and
a semiconductor buffer layer combination between the substrate and the converting structure, the semiconductor buffer layer combination comprising multiple first semiconductor layers and multiple second semiconductor layers alternately stacked, wherein each of the multiple first semiconductor layers comprises a first element, each of the multiple second semiconductor layers comprises a second element different from the first element, and the composition ratio of the first element gradually increases or decreases with an increase of the distance between the first semiconductor layers and the substrate.

2. The optoelectronic device as claimed in claim 1, wherein the composition ratio of the second element gradually increases or decreases with an increase of the distance between the second semiconductor layers and the substrate.

3. The optoelectronic device as claimed in claim 1, wherein a lattice constant of the first semiconductor layer closest to the substrate is substantially matched to the lattice constant of the substrate.

4. The optoelectronic device as claimed in claim 1, wherein a lattice constant of the second semiconductor layer closest to the converting structure is substantially matched to the lattice constant of the converting structure.

5. The optoelectronic device as claimed in claim 1, wherein a lattice constant of each of the multiple first semiconductor layers is substantially matched to the lattice constant of an adjacent one of the multiple second semiconductor layers.

6. The optoelectronic device as claimed in claim 1, wherein a thickness of each of the multiple first semiconductor layers gradually increases or decreases with an increase of the distance between the each of the multiple first semiconductor layers and the substrate.

7. The optoelectronic device as claimed in claim 1, wherein the first semiconductor layer comprises GaₓIn₁₋ₓP, and the second semiconductor layer comprises Al_{y}In_{1-y}P, wherein 0.1<x, y<0.6.

8. The optoelectronic device as claimed in claim 7, wherein the substrate comprises GaAs.

9. The optoelectronic device as claimed in claim 8, wherein the converting structure comprises InₐGa₍₁₋ₐ₎As (0<a<0.5).

10. The optoelectronic device as claimed in claim 1, wherein the first semiconductor layer which is closest to the substrate comprises Ga_{0.49}In_{0.51}P and the second semiconductor layer which is closest to the substrate comprises Al_{0.49}In_{0.51}P.

11. The optoelectronic device as claimed in claim 1, further comprising a plurality of quantum dots between the substrate and the semiconductor buffer layer combination.

12. The optoelectronic device as claimed in claim 1, wherein the converting structure is a solar subcell or a light-emitting stack.

13. The optoelectronic device as claimed in claim 1, wherein the converting structure comprises a p-n junction for converting light into electrical current.

14. The optoelectronic device as claimed in claim 13, further comprising a second p-n junction between the substrate and the semiconductor buffer layer combination for converting light into electric current, wherein the second p-n junction has a band gap smaller than that of the p-n junction.

15. The optoelectronic device as claimed in claim 14, wherein the semiconductor buffer layer combination reflects a part of incident light which is substantially not absorbed by the second p-n junction and has a reflectivity greater than 70%.

16. The optoelectronic device as claimed in claim 14, wherein the semiconductor buffer layer combination reflects a part of incident light which comprises a wavelength substantially shorter than 880 nm and has a reflectivity greater than 70%.

17. The optoelectronic device as claimed in claim 14, wherein the converting structure comprises a p-type GaAs layer and an n-type GaAs layer and the second p-n junction comprises a p-type In_{b}Ga_{(1-b)}As layer and an n-type In_{b}Ga_{(1-b)}As layer where 0<b<1.

18. The optoelectronic device as claimed in claim 17, wherein the multiple first semiconductor layers comprise GaₓIn₁₋ₓP, and the multiple second semiconductor layers comprise Al_{y}In_{1-y}P, wherein 0.1<x, y<0.6.

19. The optoelectronic device as claimed in claim 18, further comprising a tunneling junction between the converting structure and the semiconductor buffer layer combination.

20. The optoelectronic device as claimed in claim 19, wherein the tunneling junction comprises a GaAs layer close to the semiconductor buffer layer combination and a Al_{c}Ga_{(1-c)}As (0<c<1) layer remote from the semiconductor buffer layer combination.
